(19) United States
(12) Patent Application Publication
(10) Pub. No.: US 2005/0276019 A1
(43) Pub. Date: Dec. 15, 2005

(54) Computer temperature management system and method

(75) Inventor: Su-chul Yoon, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 11/146,151

(22) Filed: Jun. 7, 2005

(30) Foreign Application Priority Data
Jun. 10, 2004 (KR) 2004-42581

(51) Int. Cl. H05K 7/20

(52) U.S. Cl. 361/695

(57) ABSTRACT

A computer system including a main circuit, a main cooling fan cooling the main circuit, a detector detecting a driving state of the main circuit, a power supply which supplies driving power to the main cooling fan, a second circuit, a second cooling fan supplied with driving power branched from the driving power supplied from the power supply to the main cooling fan to cool the second circuit, and a controller controlling the power supply so as to supply the driving power to the main cooling fan based on a detecting signal from the detector. Thus, embodiments of the present invention provide for a computer system that does not require separated controlling circuits driving of separate added cooling fans, including a main cooling fan, but through a controlling circuit that controls driving of the main cooling fan and an additional added cooling fan, thereby improving layout efficiency and decreasing manufacturing cost.

### CROSS-REFERENCE TO RELATED APPLICATIONS

This application claims the priority benefit of Korean Patent Application No. 2004-0042581, filed Jun. 10, 2004, in the Korean Intellectual Property Office, the disclosure of which is incorporated herein by reference.

### BACKGROUND OF THE INVENTION

1. Field of the Invention

The present invention relates to a computer system, and more particularly, to a computer system which does not require separated controlling circuits for driving added cooling fans, through a controlling circuit which controls driving of a main cooling fan, thereby improving layout efficiency and decreasing manufacturing costs.

2. Description of the Related Art

Nowadays, computer system processors are being sped up, resulting in increased consumed power of peripheral chipsets and the computer system. For example, a computer having a Pentium-4™ CPU needs over 300 W of power, so a cooling fan cooling the computer has become necessary.

The consumed power of the computer is variable, and as load increases, the consumed power also increases, in proportion to the load. When the cooling fan cooling the the CPU is invariably driven, i.e., without any relation with amount of consumed power of the CPU, the cooling fan is invariably driven even though the consumed power is low, because of the little load on the CPU. Accordingly, the cooling fan overcools the CPU and generates unnecessary noise.

A conventional computer typically includes a controlling circuit which controls a driving of the cooling fan, according to the consumed power in driving of CPU, and solves the problem of overcooling and over-noise. Generally, this conventional computer arrangement shows a tendency of including, separately, a cooling fan for a chipset for a graphic board as well as the CPU, so as to efficiently cool most of the prime heat generators within the computer system.

This conventional computer solves the problem of the overcooling and the over-noise as follows. The computer includes an auxiliary controlling circuit, as well as a main controlling circuit controlling the driving of the cooling fan of the CPU, so that the cooling fan of the graphic board can be controlled according to an amount of consumed power of the chipset for the graphic board. However, to comprise the auxiliary controlling circuit, a separated space in the layout of the graphic board is needed, which increases manufacturing costs.

### SUMMARY OF THE INVENTION

Accordingly, it is an aspect of the present invention to provide a computer system and method which does not require separated controlling circuits, and which controls a driving of added cooling fans through a controlling circuit that controls a driving of a main cooling fan, improving layout efficiency and decreasing manufacturing costs.

Additional aspects and/or advantages of the invention will be set forth in part in the description which follows and, in part, will be obvious from the description, or may be learned by practice of the invention.

To achieve the above and/or other aspects and advantages, embodiments of the present invention set forth a computer system, including a main circuit, a main cooling fan to cool the main circuit, a detector to detect a driving state of the main circuit, a power supply to supply driving power to the main cooling fan, a second circuit, a second cooling fan supplied with driving power branched from the driving power supplied to the main cooling fan, to cool the second circuit, and a controller controlling the power supply so as to control the driving power output from the power supply, and input to the main cooling fan, based on a detecting signal from the detector.

The detector may include a temperature detecting sensor detecting a temperature of the main circuit and outputting a temperature detecting signal to the controller, and the controller may control the power supply based on the temperature detecting signal from the temperature detecting sensor to modulate the driving power output to the main cooling fan so as to control a rotating velocity of the main cooling fan according to the temperature of the main circuit.

Further, the main circuit may include a CPU, and the second circuit may include a graphic board outputting an image signal. The computer system may include a display displaying an image according to the image signal from the graphic board.

In addition, the computer system may further include a power modulator placed on a driving power supplying path supplying the branched driving power to the second cooling fan, modulating an amount of the branched driving power supplied to the second cooling fan.

The computer system with the modulator may include a temperature detecting sensor detecting a temperature of the main circuit and outputting a temperature detecting signal to the controller, with the controller controls the power supply based on the temperature detecting signal from the temperature detecting sensor to modulate the driving power output to the main cooling fan so as to control a rotating velocity of the main cooling fan according to the temperature of the main circuit. The power modulator may be a variable resistor.

Further, the computer system may include a consumed power detector detecting an amount of consumed power of the main circuit and outputting a consumed power detecting signal to the controller, with the controller controls the power supply based on the consumed power detecting signal from the consumed power detector to modulate the driving power output to the main cooling fan so as to control a rotating velocity of the main cooling fan.

In addition, the main cooling fan and the second cooling fan may rotate with an identical velocity. The second cooling fan rotation velocity may also be variably dependent with a rotation velocity of the main cooling fan. The variable dependency can be based on a power modulator placed between the power supply and the second cooling fan modifying the branched driving power, with the power modulator potentially being a variable resistor.

To achieve the above and/or other aspects and advantages, embodiments of the present, invention include a computer cooling method, including detecting a driving state of a main circuit in a computer system, supplying driving power to a main cooling fan of the main circuit, supplying a second cooling fan with branched driving power, branched from the driving power supplied to the main cooling fan, to cool a second circuit, and controlling the supplying of driving power so as to control the driving power output to the power supply, and input to the main cooling fan, based on a detecting signal generated during the detecting of the driving state of the main circuit.

The detecting of the driving state of the main circuit may further include detecting a temperature of the main circuit and outputting the detecting signal, as a temperature detecting signal, to the controller, wherein the controlling of the supplying of driving power may further include controlling the driving power based on the temperature detecting signal to modulate the driving power output to the main cooling fan so as to control a rotating velocity of the main cooling fan according to the temperature of the main circuit.

The method may further include modulating the branched driving power, on a driving power supplying path supplying the branched driving power to the second cooling fan, by modulating an amount of the branched driving power supplied to the second cooling fan.

In addition, the detecting of the driving state of the main circuit may similarly include detecting an amount of consumed power of the main circuit and outputting the detecting signal, as a consumed power detecting signal, to the controller, and wherein the controlling of the supplying of driving power may further include controlling the driving power based on the consumed power detecting signal to modulate the driving power output to the main cooling fan so as to control a rotating velocity of the main cooling fan.

### BRIEF DESCRIPTION OF THE DRAWINGS

These and other aspects and advantages of the general inventive concept will become apparent and more readily appreciated from the following description of the embodiments, taken in conjunction with the accompany drawings of which:

FIG. 1 is a control block diagram of a computer system, according to an embodiment of the present invention,

FIG. 2 is a flow chart of a computer system, according to an embodiment of the present invention.

### DETAILED DESCRIPTION OF THE PREFERRED EMBODIMENTS

Reference will now be made in detail to embodiments of the present invention, examples of which are illustrated in the accompanying drawings, wherein like reference numerals refer to like elements throughout. The embodiments are described below in order to explain the present invention by referring to the figures.

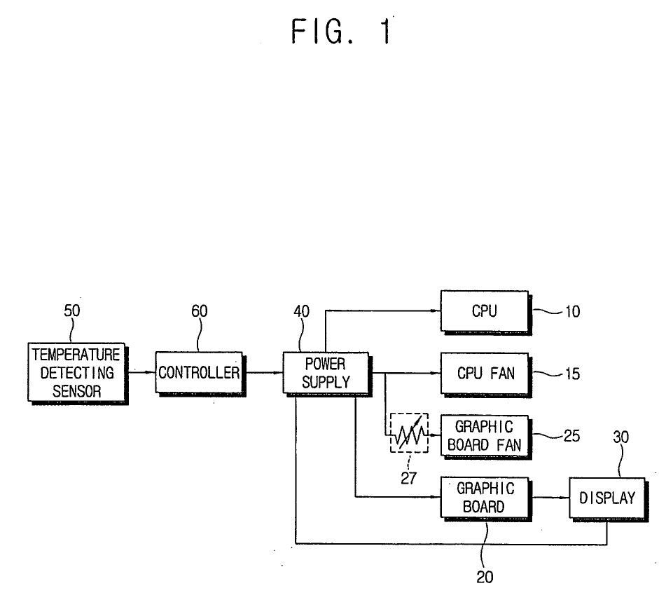

As shown in FIG. 1, a computer system, according to an embodiment of the present invention, includes: a central processing unit (CPU) 10 controlling the driving of the computer system, on the whole; a CPU fan 15 cooling the CPU 10; a graphic board 20 outputting an image signal; a power supply 40 supplying driving power to the CPU 10, the CPU fan 15, and the graphic board 20; a graphic board fan 25 being supplied with driving power branched from the driving power supplied from the power supply 40 to the CPU fan 15, and cooling the graphic board 20; a temperature detecting sensor 50 detecting the temperature of the CPU 10, and outputting a temperature detecting signal; and a controller 60 controlling the power supply 40 so as to supply the driving power to the CPU fan 15 based on the temperature detecting signal from the temperature detecting sensor 50.

Herein, the CPU 10 can be considered a first circuit or a main circuit, and the graphic board 20 can be considered a second circuit or an auxiliary circuit. Further, the CPU fan 15 can be considered a first circuit fan or a main circuit fan, and the graphic board fan 25 can be considered a second circuit fan or an auxiliary circuit fan.

In embodiments of the present invention, the power supply 40 can supply driving power to the CPU 10 and the graphic board 20, and supply the driving power to the CPU fan 15 by modulating the amount of the driving power to the CPU fan 15, based on a controlling of the controller 60.

Meanwhile, the computer system according to an embodiment of the present invention further includes a display 30 displaying an image according to the image signal output from the graphic board 20. Herein, the display 30 may be driven according to the driving power from the power supply 40 or from a separate external power supply.

The graphic board fan 25 cools the graphic board 20, and can be driven with the driving power branched from the driving power supplied from the power supply 40 to the CPU fan 15. In other words, the graphic board fan 25 is supplied with the same driving power as the driving power supplied to the CPU fan 15, and is thereby driven with the same rotating velocity as that of the CPU fan 15.

The controller 60 controls the power supply 40, based on the temperature detecting signal from the temperature detecting sensor 50, to modulate the amount of the driving power supplied to the CPU fan 15 to control the rotating velocity of the CPU fan 15 according to the temperature of the CPU 10. For example, when the temperature of the CPU 10, based on the temperature detecting signal from the temperature detecting sensor 50, is lower than a predetermined reference temperature, the power supply 40 is controlled so as to supply lower power than the predetermined reference power to the CPU fan 15.

As shown in FIG. 1, in an embodiment of the present invention, a driving state of the CPU 10 can be detected based on the temperature detecting sensor 50. In addition, a consumed power detector detecting an amount of consumed power of the CPU 10, i.e., the amount of the driving power supplied to the CPU 10, may also be included therein and the controller 60 may control the power supply 40 based on a CPU consumed power detecting signal output to modulate the amount of the driving power supplied to the CPU fan 15, thereby controlling the rotating velocity of the CPU fan 15. Accordingly, a detector detecting the driving state, such as the temperature of the CPU 10 and the amount of the driving power supplied to the CPU 10, can be variously provided therein.

As described above, the graphic board fan 25 can be supplied with the same driving power as the CPU fan 15, and accordingly can be driven with the same rotating velocity as the CPU fan 15. Herein, the driving power for an ideal rotating velocity may vary, due to each property of the CPU fan 15 and the graphic board fan 25, and a margin of the circuit design, etc. However, as shown in table 1, according to a result of a simple test, when rotation of the CPU fan 15 and the graphic board fan 25 are controlled by supplying the same driving power to the CPU fan 15 and the graphic board fan 25, it has little effect on the CPU fan 15 and graphic board fan 25 to work respectively.

TABLE 1

| | | After the invention, | | | |
|---|---|---|---|---|---|
| | | the CPU is in a normal | | When the CPU is | |
| | Before the | state (RPM which is | | heated (RPM which | |
| | invention | approximately 2000) | | is approximately | |
| | (RPM) | | Graphic | 4000) | |
| A section | CPU fan | CPU fan | board fan | | CPU fan |
| DOS | 1578 | 2189 | 2201 | DOS | 1578 |
| Mode | | | | Mode | |
| Windows | 2007 | 2208 | 2304 | Windows | 2007 |
| Mode | | | | Mode | |
| 3D Mark | 2474 | 2701 | 2875 | 3D Mark | 2474 |
| 2003 | | | | 2003 | |
| Win Daig | 2399 | 2643 | 2801 | Win Daig | 2399 |

However, considering the margin of the circuit design, a driving power supplying path supplying the driving power to the graphic board fan 25 may include a power modulator modulating the amount of power supplied to the graphic board fan 25. As shown in FIG. 1, a variable resister 27, as the power modulator, may also be placed on the driving power supplying path of the graphic board fan 25. Accordingly, the driving power supplied to the graphic board fan 25, which was the same as the driving power supplied to the CPU fan 15, can be modulated, in detail, through the variable resistor 27 so that an ideal driving power for an ideal rotating velocity of the graphic board fan 25 can be accordingly provided.

An embodiment of the present invention, without the variable resistor 27 is described below.

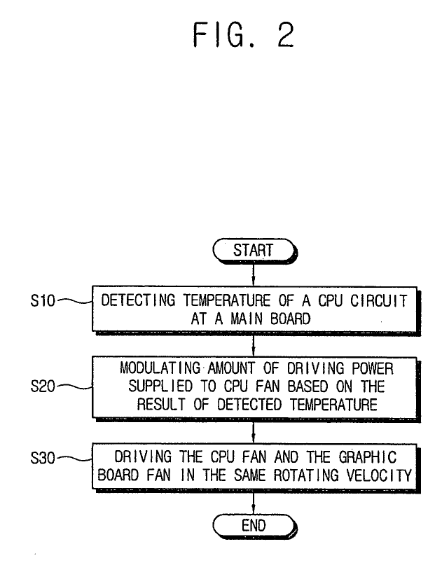

A controlling flow of the computer system according to embodiments of the present invention now follows, referring to FIG. 2. First, the temperature detecting sensor 50 can detect the temperature of the CPU 10 at the main board and output a temperature detecting signal to the controller 60, in operation S10. The controller 60 controls the power supply 40 to modulate the rotating velocity of the CPU fan 15, based on the temperature detecting signal input from the temperature detecting sensor 50. Then, the graphic board fan 25 is supplied with driving power branched from the driving power supplied from the power supply 40 to the CPU fan 15, i.e., the same driving power as the driving power supplied to the CPU fan 15, in operation S20. Accordingly, the CPU fan 15 and the graphic board fan 25 are respectively driven at the same rotating velocity, in operation S30.

The computer system, according to embodiments of the present invention, doesn't require a separate controlling circuit for the graphic board fan 25. Instead, the graphic board fan 25 is controlled by the controller 60 controlling the CPU fan 15, of the main board, so that the graphic board fan 25 rotates at a minimum velocity (i.e. an idle state where noise is minimized) the same as that of the CPU fan 15, e.g., in an initial DOS mode or a Windows default mode. If load increases, the controller 60 controls the power supply 40 so that the rotating velocity of the CPU fan 15 is increased, then the rotating velocity of the graphic board fan 25 is similarly increased the same amount as that of the CPU fan 15.

Although a few embodiments of the present invention have been shown and described, it will be appreciated by those skilled in the art that changes may be made in these embodiments without departing from the principles and spirit of the invention, the scope of which is defined in the appended claims and their equivalents.

1. A computer system, comprising:
a main circuit;
a main cooling fan to cool the main circuit;
a detector to detect a driving state of the main circuit;
a power supply to supply driving power to the main cooling fan;
a second circuit;
a second cooling fan supplied with driving power branched from the driving power supplied to the main cooling fan, to cool the second circuit; and
a controller controlling the power supply so as to control the driving power output from the power supply, and input to the main cooling fan, based on a detecting signal from the detector.

2. The computer system of claim 1, wherein the detector comprises a temperature detecting sensor detecting a temperature of the main circuit and outputting a temperature detecting signal to the controller, and the controller controls the power supply based on the temperature detecting signal from the temperature detecting sensor to modulate the driving power output to the main cooling fan so as to control a rotating velocity of the main cooling fan according to the temperature of the main circuit.

3. The computer system of claim 2, wherein the main circuit comprises a CPU, and the second circuit comprises a graphic board outputting an image signal.

4. The computer system of claim 3, further comprising a display displaying an image according to the image signal from the graphic board.

5. The computer system of claim 1, further comprising a power modulator placed on a driving power supplying path supplying the branched driving power to the second cooling fan, and modulating an amount of the branched driving power supplied to the second cooling fan.

6. The computer system of claim 5, wherein the detector comprises a consumed power detector detecting an amount of consumed power of the main circuit and outputting a consumed power detecting signal to the controller, and the controller controls the power supply based on the consumed power detecting signal from the consumed power detector to modulate the driving power output to the main cooling fan so as to control a rotating velocity of the main cooling fan.

7. The computer system of claim 1, wherein the detector comprises a consumed power detector detecting an amount of consumed power of the main circuit and outputting a consumed power detecting signal to the controller, and the controller controls the power supply based on the consumed power detecting signal from the consumed power detector to modulate the driving power output to the main cooling fan so as to control a rotating velocity of the main cooling fan.

8. The computer system of claim 1, wherein the main cooling fan and the second cooling fan rotate with an identical velocity.

9. The computer system of claim 1, wherein a fan rotation velocity of the second cooling fan is variably dependent with a rotation velocity of the main cooling fan.

10. The computer system of claim 9, wherein the variable dependency is based on a power modulator placed between the power supply and the second cooling fan modifying the branched driving power.

11. A computer cooling method, comprising:
detecting a driving state of a main circuit in a computer system;
supplying driving power to a main cooling fan of the main circuit;
supplying a second cooling fan with branched driving power, branched from the driving power supplied to the main cooling fan, to cool a second circuit; and
controlling the supplying of driving power so as to control the driving power output to the power supply, and input to the main cooling fan, based on a detecting signal generated during the detecting of the driving state of the main circuit.

12. The method of claim 11, wherein the detecting of the driving state of the main circuit further comprises detecting a temperature of the main circuit and outputting the detecting signal, as a temperature detecting signal, to the controller, and wherein the controlling of the supplying of driving power further comprises controlling the driving power based on the temperature detecting signal to modulate the driving power output to the main cooling fan so as to control a rotating velocity of the main cooling fan according to the temperature of the main circuit.

13. The method of claim 12, wherein the main circuit comprises a CPU, and the second circuit comprises a graphic board outputting an image signal.

14. The method of claim 13, further comprising a display displaying an image according to the image signal from the graphic board.

15. The method of claim 11, further comprising modulating the branched driving power, on a driving power supplying path supplying the branched driving power to the second cooling fan, by modulating an amount of the branched driving power supplied to the second cooling fan.

16. The method of claim 15, wherein the detecting of the driving state of the main circuit further comprises detecting an amount of consumed power of the main circuit and outputting the detecting signal, as a consumed power detecting signal, to the controller, and wherein the controlling of the supplying of driving power further comprises controlling the driving power based on the comsumed power detecting signal to modulate the driving power output to the main cooling fan so as to control a rotating velocity of the main cooling fan.

17. The method of claim 11, wherein the main cooling fan and the second cooling fan rotate with an identical velocity.

18. The method of claim 11, wherein a fan rotation velocity of the second cooling fan is variably dependent with a rotation velocity of the main cooling fan.

19. The method of claim 18, wherein the variable dependency is based on a modifying of the branched driving power between the power supply and the second cooling fan.
